(19) United States
(12) Patent Application Publication
(10) Pub. No.: US 2021/0356808 A1
(43) Pub. Date: Nov. 18, 2021

(54) A DEVELOPING DEVICE AND A DEVELOPING METHOD OF SUBSTRATE

(71) Applicant: WUHAN CHINA STAR OPTOELECTRONICS TECHNOLOGY CO., LTD., Wuhan (CN)

(72) Inventor: Peng Ding, Wuhan (CN)

(21) Appl. No.: 16/463,237

(22) PCT Filed: Dec. 4, 2018
(86) PCT No.: PCT/CN2018/119243

§ 371 Date: May 22, 2019

(30) Foreign Application Priority Data
Oct. 29, 2018 (CN) 201811271898.0

(51) Int. Cl. G02F 1/1335; G02F 1/13

(52) U.S. Cl. CPC G02F 1/133516; G02F 1/1303

(57) ABSTRACT

A developing device and a developing method of substrate are provided. The developing device comprises: a conveying platform and a spraying mechanism disposed above the conveying platform; the spraying mechanism comprising a spraying pipe; a plurality of first nozzles and a plurality of second nozzles disposed on the spraying pipe. The conveying platform is used for conveying a substrate, and tilting the substrate with respect to the horizontal direction during a conveying process. The first nozzles are used for spraying a chemical solution onto the substrate continuously; the second nozzles are used for starting or ending spraying the chemical solution onto the substrate according to a predetermined spray density.

### FIELD OF INVENTION

The present invention relates to the technical field of display, in particular to a developing device and a developing method of a substrate.

### BACKGROUND OF INVENTION

Thin film transistor (TFT) is the main drive component in current liquid crystal display (LCD) and active matrix organic light-emitting diode (AMOLED), which directly affects display performance of flat panel display devices.

Most LEDs in the current market are backlit LEDs, which comprise a liquid crystal display panel and a backlight module. The working principle of the liquid crystal display panel is that the liquid crystal molecules are poured between the thin film transistor array substrate and the color filter (CF) substrate, and a pixel voltage and a common voltage are respectively applied to the two substrates, and the rotation direction of the liquid crystal molecules is controlled by means of an electric field formed between the pixel voltage and the common voltage, thereby transmitting the light from the backlight module to generate an image.

As the small-sized TFT-LCD has become finer and finer, the corresponding manufacturing equipments are continuously updated so as to satisfy the processing requirements. Take sixth-generation Low Temperature Poly-silicon (LTPS) production line for instance, the way of conveying a substrate has been changed from horizontal conveying to inclined conveying in the developing machine which is used in manufacturing CF substrate. The inclined conveying has the following advantages: 1. The flow direction of a chemical solution is relatively consistent so that the possibility of mura occurs on the substrate can be reduced. 2. The effect of the drying process on the substrate is relatively good because the required blowing force during the drying process is relatively small, and the possibility of mura occurs on the substrate is reduced. 3. The capability to control over regional concentration is relatively good because the replacement rate of old and new chemical solution is relatively high, and the cleaning capacity is relatively high, which is conducive to saving deionized water. 4. A liquid film of the chemical solution is relatively thin, which is beneficial to reduce liquid holdup. In spite of the advantages of the inclined conveying mode, it still has the defects of: 1. The guide roller wears more seriously, the horizontal line is adjusted frequently, and the substrate fragmentation problem is more serious. 2. The inclined part is a bottleneck of tack time, and the overall length of the equipment will be a little longer. 3. The chemical solution has a concentration gradient distribution, and the critical dimension (CD) in the substrate is in a gradient distribution, which is not conducive to controlling the consistency of the CD.

### SUMMARY OF INVENTION

The object of the invention is to provide a developing device, which can prevent a chemical solution distributed on a substrate from occurring concentration gradient, and improve the consistency of the chemical solution distributed on the substrate, and further improve the consistency of the CD in the substrate.

The object of the invention is also to provide a developing method of a substrate, which can prevent the chemical solution distributed on the substrate from occurring concentration gradient, and improve the consistency of the chemical solution distributed on the substrate, and further improve the consistency of the CD in the substrate.

In order to achieve the above-mentioned objects, the present invention provides a developing device, comprising: a conveying platform and a spraying mechanism disposed above the conveying platform; the spraying mechanism comprising a spaying pipe and a plurality of first nozzles and a plurality of second nozzles disposed on the spraying pipe.

The conveying platform is used for conveying a substrate, and tilting the substrate with respect to the horizontal direction during a conveying process;

The first nozzles are used for spraying a chemical solution onto the substrate continuously.

The second nozzles are used for starting or ending spraying the chemical solution onto the substrate according a predetermined spray density.

The conveying platform is provided with a plurality of guide rollers inclined with respect to the horizontal direction.

The substrate is inclined at an angle 5 degrees with respect to the horizontal direction.

Each of the second nozzles has a thread therein, and the second nozzle can be closed by matching a T-shaped nut with the thread.

The plurality of second nozzles are respectively disposed between each adjacent two of the first nozzles.

The present invention also provides a substrate developing method, comprising the following steps:

Step 1, providing a developing device; the developing device comprises: a conveying platform and a spraying mechanism disposed above the conveying platform; the spraying mechanism comprising a spraying pipe and a plurality of first nozzles and a plurality of second nozzles disposed on the spraying pipe;

Step 2, the conveying platform is used for conveying a substrate, and tilting the substrate with respect to the horizontal direction during a conveying process;

Step 3, the first nozzle sprays the chemical solution onto the substrate continuously; the second nozzle starts or ends spraying the chemical solution onto the substrate according to a predetermined density.

The conveying platform is provided with a plurality of guide rollers inclined with respect to the horizontal direction.

The substrate is inclined at an angle 5 degrees with respect to the horizontal direction.

Each of the second nozzles has a thread therein, and the second nozzle can be closed by matching a T-shaped nut with the thread during the Step 3.

The plurality of second nozzles are respectively disposed between each adjacent two of the first nozzles.

Advantageous effects of the present invention: The developing device of the present invention comprises: a conveying platform and a spraying mechanism disposed above the conveying platform; the spraying mechanism comprising a spraying pipe and a plurality of first nozzles and a plurality of second nozzles disposed on the spraying pipe; the conveying platform is used for conveying a substrate, and tilting the substrate with respect to the horizontal direction during the conveying process so that the flow direction of a chemical solution is relatively consistent, and the possibility that Mura occurs on the substrate is reduced; the capability to control over regional concentration is relatively good because the replacement rate of old and new chemical solution is relatively high; the blowing force required during the drying process is relatively small, further reducing the possibility that Mura occurs on the substrate. The first nozzles are used for spraying the chemical solution onto the substrate continuously. The second nozzles are used for starting or ending spraying the chemical solution onto the substrate according to a predetermined spray density, which can prevent the chemical solution distributed on the substrate from occurring concentration gradient, and improve the consistency of the chemical solution distributed on the substrate, and further improve the consistency of the the CD in the substrate. The substrate developing method of the present invention can prevent the chemical solution distributed on the substrate from occurring concentration gradient, and improve the consistency of the chemical solution distributed on the substrate, and further improve the consistency of the CD in the substrate.

### DESCRIPTION OF DRAWINGS

In order to further understand the features and technical contents of the present invention, please refer to the following detailed description and drawings regarding the present invention, the drawings are only used for providing reference and description instead of limiting the present invention.

FIG. 1 is a schematic structural diagram of a developing device according to the present invention;

FIG. 2 is a flow chart of a substrate developing method according to the present invention.

### DETAILED DESCRIPTION OF PREFERRED EMBODIMENTS

In order to further clarify the technical means and effects of the present invention, the following detailed description will be made in conjunction with the preferred embodiments of the invention and the accompanying drawings.

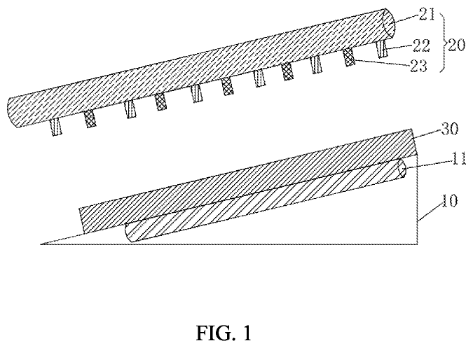

Referring to FIG. 1, the present invention provides a developing device, comprising: a conveying platform 10 and a spraying mechanism 20 disposed above the conveying platform 10; the spraying mechanism 20 comprising a spraying pipe 21; a plurality of first nozzles 22 and a plurality of second nozzles 23 disposed on the spraying pipe 21.

The conveying platform 10 is used for conveying a substrate 30, and tilting the substrate 30 with respect to the horizontal direction during the conveying process;

The first nozzles 22 are used for spraying a chemical solution onto the substrate 30 continuously;

The second nozzles 23 are used for starting or ending spraying the chemical solution onto the substrate 30 according to a predetermined spray density.

To be noted, the present invention tilts the substrate 30 with respect to the horizontal direction during the process of conveying the substrate 30 by the conveying platform 10 so that the flow direction of the chemical solution is relatively consistent, and the possibility that Mura occurs on the substrate 30 is reduced; the capability to control over regional concentration is relatively good because the replacement rate of old and new chemical solution is relatively high; the blowing force required during the drying process is relatively small, when the substrate 30 is subsequently dried by blowing, only a relatively small blowing force is required to dry the substrate 30 so that the possibility that Mura occurs on the substrate 30 is reduced. The present invention further provides the plurality of second nozzles 23 disposed on the spraying pipe 21. The second nozzle 23 starts or ends spraying the chemical solution onto the substrate 30 according to a predetermined spray density. In the actual development process, when it is necessary to increase or decrease the amount of the chemical solution on a certain area on the substrate 30, the amount of the chemical solution in a certain area on the substrate 30 can be correspondingly increased or decreased by the opening or closing of the second nozzle 23, thereby preventing the chemical solution on the substrate 30 from occurring concentration gradient, and improving the consistency of the distribution of the chemical solution, and further improving the consistency of the CD in the substrate 30. In addition, since the second nozzle 23 is provided, the conveying platform 10 is not required to be too long so that the cost of the developing device is reduced.

Specifically, the conveying platform 10 is provided with a plurality of guide rollers 11 inclined with respect to the horizontal direction, and the guide rollers 11 conveys the substrate 30 and tilts the substrate 30 with respect to the horizontal direction during the conveying process. During the developing process, the guide roller 11 is gradually worn, an inclination angle of the substrate 30 also changes along with it. The second nozzle 23 can be opened or closed in the present invention according to the inclination angle after the change without frequently adjusting the inclination angle of the guide roller 11, thereby improving the consistency of the distribution of the chemical solution, and avoiding the risk of fragmentation of the substrate 30. In addition, the spraying pipe 21 is parallel to the substrate 30, that is, the angle at which the spraying pipe 21 is inclined is the same as the angle at which the substrate 30 is inclined, so as to better spray the chemical solution onto the substrate 30.

Specifically, the angle at which the substrate 30 is inclined with respect to the horizontal direction is 5 degrees. When the chemical solution flows from one end of the substrate 30 to the other end, the possibility that Mura occurs on the substrate 30 is relatively small.

Specifically, Each of the second nozzles 23 has a thread therein, and the second nozzle 23 can be closed by matching a T-shaped nut and the thread.

Specifically, the plurality of second nozzles 23 are respectively disposed between each adjacent two of the first nozzles 22 to better adjust the spray density.

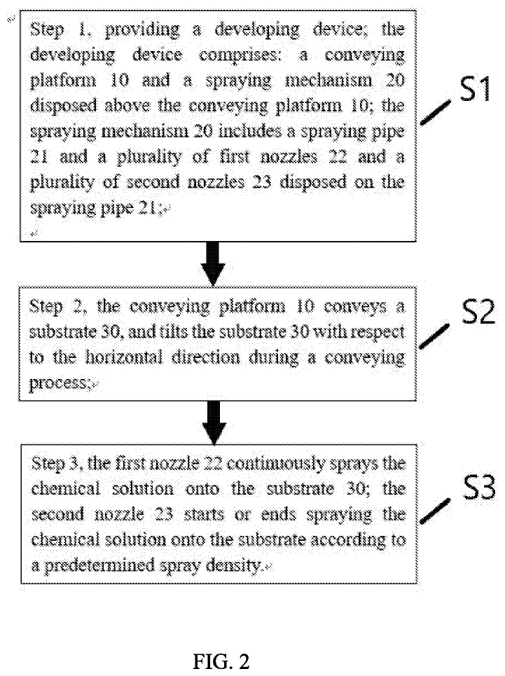

Referring to FIG. 2, based on the above developing device, the present invention also provides a substrate developing method, comprising the following steps:

Step 1, providing a developing device; the developing device comprises: a conveying platform 10 and a spraying mechanism 20 disposed above the conveying platform 10; the spraying mechanism 20 includes a spraying pipe 21 and a plurality of first nozzles 22 and a plurality of second nozzles 23 disposed on the spraying pipe 21;

Step 2, the conveying platform 10 conveys a substrate 30, and tilts the substrate 30 with respect to the horizontal direction during a conveying process;

Step 3, the first nozzle 22 continuously sprays the chemical solution onto the substrate 30; the second nozzle 23 starts or ends spraying the chemical solution onto the substrate according to a predetermined spray density.

To be noted, the present invention tilts the substrate 30 with respect to the horizontal direction during the process of conveying the substrate 30 by the conveying platform 10 so that the flow direction of the chemical solution is relatively consistent, and the possibility that Mura occurs on the substrate 30 is reduced; the replacement rate of old and new chemical solution is higher, which is beneficial to the control of regional concentration. When the substrate 30 is subsequently dried by blowing, only a relatively small blowing force is required to dry the substrate 30, thereby reducing the possibility that Mura occurs on the substrate 30. The present invention further provides a plurality of second the nozzles 23 disposed on the spraying pipe 21. The second 23 starts or ends spraying the chemical solution onto the substrate 30 according to a predetermined spray density. In the actual development process, when it is necessary to increase or decrease the amount of the chemical solution on a certain area on the substrate 30, the amount of the chemical solution in a certain area on the substrate 30 can be correspondingly increased or decreased by the opening or closing of the second nozzle 23, thereby preventing the chemical solution on the substrate 30 from occurring concentration gradient, and improving the consistency of the distribution of the chemical solution, and further improving the consistency of the CD in the substrate 30. In addition, since the second nozzle 23 is provided, the conveying platform 10 is not required to be too long so that the cost of the developing device is reduced.

Specifically, the conveying platform 10 is provided with a plurality of guide rollers 11 inclined with respect to the horizontal direction, and the guide rollers 11 convey the substrate 30 and can tilt the substrate 30 with respect to the horizontal direction during the conveying process. During the developing process, the guide roller 11 is gradually worn, an inclination angle of substrate 30 also changes along with it. In the present invention, the second nozzle 23 can be opened or closed according to the inclination angle after the change to improve the consistency of the distribution of the chemical solution, without frequently adjusting the inclination angle of the guide roller 11, thereby avoiding the risk of fragmentation of the substrate 30. In addition, the spraying pipe 21 is parallel to the substrate 30, that is, the angle at which the spraying pipe 21 is inclined is the same as the angle at which the substrate 30 is inclined, which is beneficial to spray the chemical solution onto the substrate 30.

Specifically, the angle at which the substrate 30 is inclined with respect to the horizontal direction is 5 degrees. When the chemical solution flows from one end of the substrate 30 to the other end, the possibility that Mura occurs on the substrate 30 is relatively small.

Specifically, Each of the second nozzles 23 has a thread therein, and the second nozzle 23 can be closed by matching a T-shaped nut and the thread during the Step 3.

Specifically, the plurality of second nozzles 23 are respectively disposed between each adjacent two of the first nozzles 22 to better adjust the spray density.

In summary, The developing device of the present invention comprises: a conveying platform and a spraying mechanism disposed above the conveying platform; the spraying mechanism comprising a spraying pipe and a plurality of first nozzles and a plurality of second nozzles on the spraying pipe; the conveying platform is used for conveying a substrate, and tilting the substrate with respect to the horizontal direction during the conveying process so that the flow direction of a chemical solution is relatively consistent, and the possibility that Mura occurs on the substrate is reduced; The capability to control over regional concentration is relatively good because the replacement rate of old and new chemical solution is relatively high, further reducing the possibility that Mura occurs on the substrate. The first nozzles are used for spraying the chemical solution onto the substrate continuously. The second nozzles are used for starting or ending spraying the chemical solution onto the substrate according to a predetermined spray density, which can prevent the chemical solution distributed on the substrate from occurring concentration gradient, and improve the consistency of the chemical solution distributed on the substrate, and further improve the consistency of the CD in the substrate. The substrate developing method of the present invention can prevent the chemical solution distributed on the substrate from occurring concentration gradient, and improve the consistency of the chemical solution distributed on the substrate, and further improve the consistency of the CD in the substrate.

In summary, various other corresponding changes and modifications can be made by those skilled in the art according to the technical solutions and technical ideas of the present invention, and all such changes and modifications are intended to fall within the scope of the appended claims.

What is claimed is:

1. A developing device, comprising: a conveying platform and a spraying mechanism disposed above the conveying platform; the spraying mechanism comprising a spraying pipe; a plurality of first nozzles and a plurality of second nozzles disposed on the spraying pipe;
the conveying platform used for conveying a substrate, and tilting the substrate with respect to the horizontal direction during a conveying process;
the first nozzles used for spraying a chemical solution onto the substrate continuously;
the second nozzles used for starting or ending spraying the chemical solution onto the substrate according to a predetermined spray density.

2. The developing device as claimed in claim 1, wherein a plurality of guide rolls inclined with respect to a horizontal direction are provided in the conveying platform.

3. The developing device as claimed in claim 1, wherein the substrate is inclined at an angle 5 degrees with respect to the horizontal direction.

4. The developing device as claimed in claim 1, wherein each of the second nozzles has a thread therein, and the second nozzle can be closed by matching a T-shaped nut and the thread.

5. The developing device as claimed in claim 1, wherein the plurality of second nozzles are respectively disposed between each adjacent two of the first nozzles.

6. A substrate developing method comprises the steps of:
Step 1, providing a developing device; the developing device comprises: a conveying platform and a spraying mechanism disposed above the conveying platform; the spraying mechanism comprises a spraying pipe and a plurality of first nozzles and a plurality of second nozzles disposed on the spraying pipe;
Step 2, the conveying platform conveys the substrate, and tilts the substrate with respect to a horizontal direction during a conveying process;
Step 3, the first nozzle continuously sprays a chemical solution onto the substrate; the second nozzle starts or ends spraying the chemical solution onto the substrate according to a predetermined spray density.

7. The substrate developing method as claimed in claim 6, wherein the conveying platform is provided with a plurality of guide rolls inclined with respect to the horizontal direction.

8. The substrate developing method as claimed in claim 6, wherein the substrate is inclined at an angle 5 degrees with respect to the horizontal direction.

9. The substrate developing method as claimed in claim 6, wherein each of the second nozzles has a thread therein, and the second nozzle can be closed by matching a T-shaped nut and the thread during the Step 3.

10. The substrate developing method as claimed in claim 6, wherein the plurality of second nozzles are respectively disposed between each adjacent two of the first nozzles.
